(19) United States
(12) Patent Application Publication
(10) Pub. No.: US 2007/0208973 A1
(43) Pub. Date: Sep. 6, 2007

(54) PCI-E debug card

(76) Inventors: Chun-Hsien Wu, Tao Yuan Shien (TW); Chin-Hao Kuo, Tao Yuan Shien (TW)

Correspondence Address: RABIN & BERDO, P.C., Suite 500, 1101 14 Street, N.W., Washington, DC, 20005, US

(21) Appl. No.: 11/404,835

(22) Filed: Apr. 17, 2006

(30) Foreign Application Priority Data
Jan. 12, 2006 (TW) 95101268

(51) Int. Cl. G01R 31/28

(52) U.S. Cl. 714/724

(57) ABSTRACT

A PCI-E debug card includes an insertion part, a low-pin-count pin set, a power pin, a ground pin, a decoder and a display unit. The insertion part is for connecting to a PCI-E slot. The low-pin-count pin set includes a reset pin, a clock pin and a plurality of data pins, each of which corresponds to reserved pins of the PCI-E slot. The power pin and the ground pin are disposed on the insertion part and correspond respectively to a slot power pin and a slot ground pin of the slot. The decoder decodes test data from the low-pin-count pin set to be a post code which is then showed by the display unit.

### RELATED APPLICATIONS

The present application is based on, and claims priority from, Taiwan Application Serial Number 95101268, filed Jan. 12, 2006, the disclosure of which is hereby incorporated by reference herein in its entirety.

### BACKGROUND

1. Field of Invention

The present invention relates to a debug card. More particularly, the present invention relates to a debug card applicable for a PCI-Express slot.

2. Description of Related Art

In computer architecture, the microprocessor usually delivers port data to peripheral devices via different buses, such as ISA (Industry Standard Architecture), PCI (Peripheral Component Interconnect), and LPC (Low Pin Count). A port number is assigned to all port data before delivery to the buses. During the data transmission process, the microprocessor first broadcasts all port data with different port numbers to the buses. Each peripheral device retrieves the port data with a specific port number from the buses according to the preset configuration.

For example, during the computer initiation procedure, the initiation result is output to a message display device via this protocol. The microprocessor first retrieves commands required for Power On Self Test (POST) from the Basic Input Output System (BIOS) during the computer initiation procedure. After executing each command, a corresponding debug port data containing the test result is broadcast to different buses, such as ISA, PCI, or LPC. The debug port data is 8-bit and on port number 80.

Afterward, a decoder connected to one of those buses and capable of decoding debug port data retrieves the debug port data from the bus for decoding. For example, an external port 80 debug card can be connected to the ISA or PCI and retrieve the debug data. Alternatively, a built-in hardware decoder connected to the LPC can be employed. After decoding, the debug port data can further be output to a message display device, so the administrator can realize the message represented by the debug port data.

New bus interface specifications for higher transfer rates such as PCI Express (PCI-E) have been developed as computer technology grows. The conventional ISA bus interface has almost been phased out, as well as the PCI interface. Therefore, the PCI-E bus interface has the best chance to be a mainstream extension slot interface in the future.

However, unlike debug cards for ISA or PCI bus interfaces, a PCI-E debug card is not available in present computer motherboards because a debug message generated from Power On Self Test (POST) can only be transmitted through the ISA, PCI or LPC bus. Thus, the PCI-E bus interface cannot be directly utilized to produce a debug card with the same purposes as described above.

For the foregoing reasons, there is a need for a debug card applicable for future computer systems without the conventional PCI bus interface, allowing users or maintenance persons to be notified of the status of the computer to resolve a problem promptly.

### SUMMARY

It is therefore an aspect of the present invention to provide a PCI-E debug card for notifying users of POST code reports.

It is another aspect of the present invention to provide a PCI-E debug card for showing a POST code through a PCI-E interface slot.

In accordance with the foregoing and other aspects of the present invention, a PCI-E debug card is provided, including an insertion part, a low-pin-count pin set, a power pin, a ground pin, a decoder and a display unit. The insertion part is for connecting to the PCI-E slot and the low-pin-count pin set is disposed on the insertion part. The low-pin-count pin set includes a reset pin, a clock pin and a plurality of data pins which correspond to reserved pins of the PCI-E slot.

The power pin disposed on the insertion part corresponds to a slot power pin of the PCI-E slot and is electrically connected with a power source, serving as a power transmission path. The ground pin disposed on the insertion part corresponds to a slot ground pin of the PCI-E slot and is electrically connected with ground, serving as a ground. The decoder decodes test data from the low-pin-count pin set to be a POST code and the display unit then shows the POST code as an error indication for users.

According to a preferred embodiment, the PCI-E debug card is a Mini PCI-E interface card applied to a Mini PCI-E slot on a laptop computer. A circuit board is the main body of the debug card and has an insertion part on the circuit board. Five data pins and a reset pin are disposed on the bottom side of the insertion part, responsible for transmission of signals defined in the LPC interface specification: LAD [3:0], LFRAME# and LRESET#. The clock pin is disposed on the top side of the insertion part, responsible for transmission of the signal LCLK defined in the LPC specification. A plurality of reserved pins of the debug card are further disposed on the top side of the insertion part.

In conclusion, by employing the reserved pins defined in the PCI-E interface specification, a debug card performing a POST report through the PCI-E interface slot is available. As the trend to replace PCI interface with PCI-E interface in computer application is gaining momentum, the present invention is becoming more and more valuable.

Especially for laptop computer systems requiring a small form factor design, the PCI-E interface is an important application, and the invention thus provides an easier troubleshooting procedure for it.

It is to be understood that both the foregoing general description and the following detailed description are by examples and are intended to provide further explanation of the invention as claimed.

### BRIEF DESCRIPTION OF THE DRAWINGS

These and other features, aspects and advantages of the present invention will become better understood with regard to the following description, appended claims and accompanying drawings where:

FIG. 1 is a schematic diagram of a PCI-E debug card in accordance with a preferred embodiment of the present invention;

FIG. 2A is a pin assignment on the bottom side of a PCI-E debug card in accordance with a preferred embodiment of the present invention; and

FIG. 2B is a pin assignment on the top side of a PCI-E debug card in accordance with a preferred embodiment of the present invention.

### DESCRIPTION OF THE PREFERRED EMBODIMENTS

The present invention provides a PCI-E debug card which displays a POST code through a PCI-E slot. The present invention employs reserved pins defined in the PCI-E specification as signal pins complying with the LPC interface specification to report the POST code through a PCI-E slot.

Reference is now made in detail to the present preferred embodiments of the invention, examples of which are illustrated in the accompanying drawings. Wherever possible, the same reference numbers are used in the drawings and the description to refer to the same or like parts.

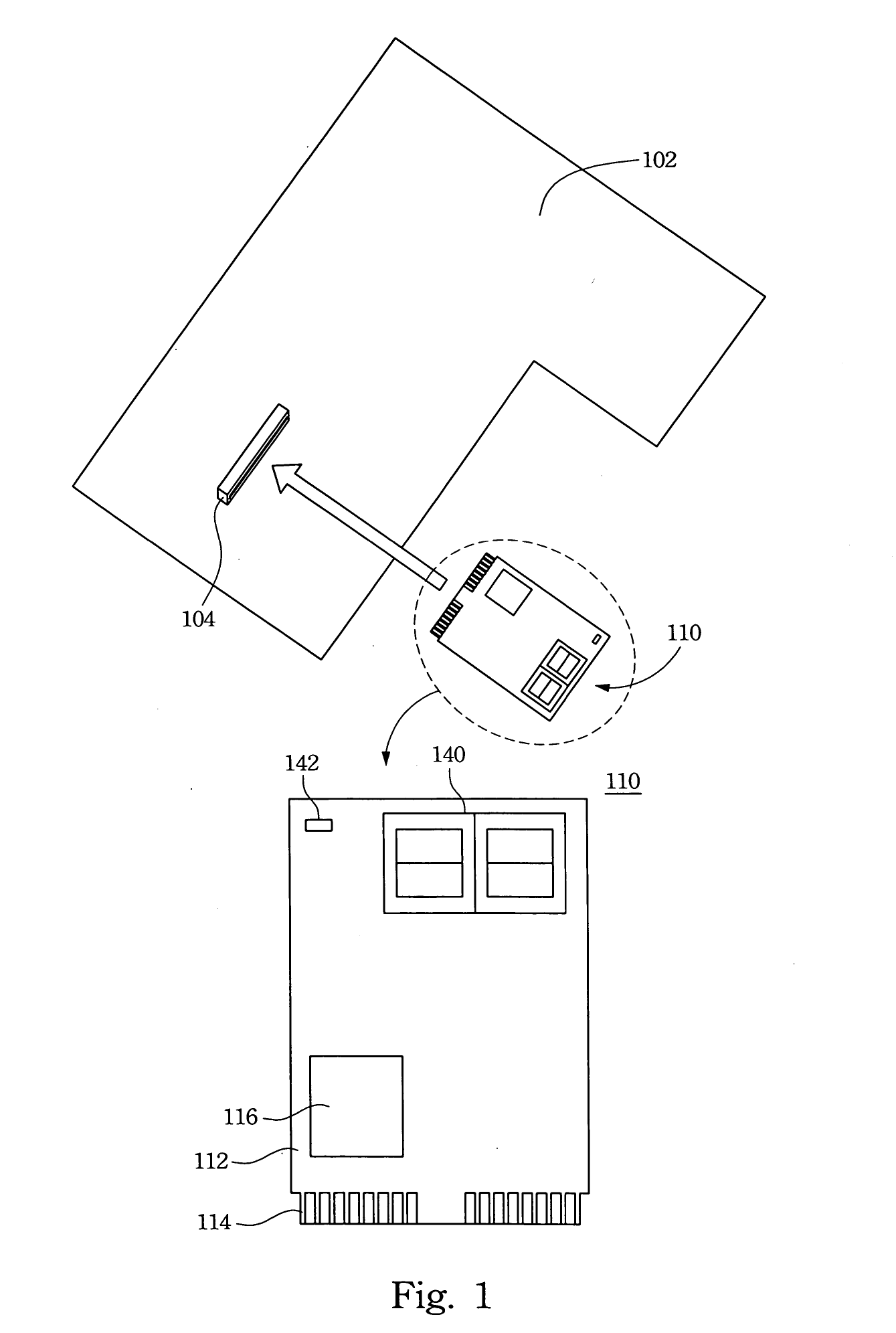

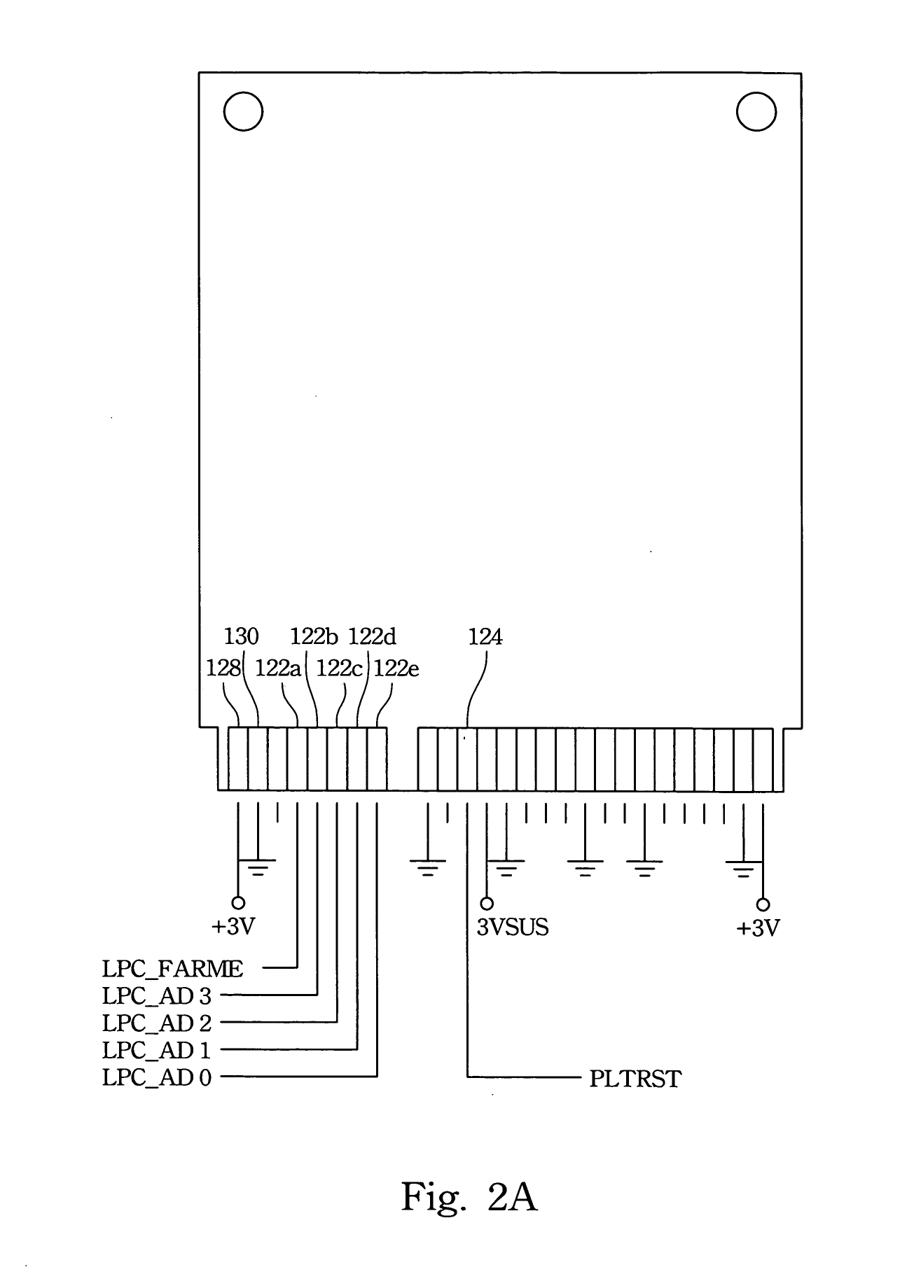

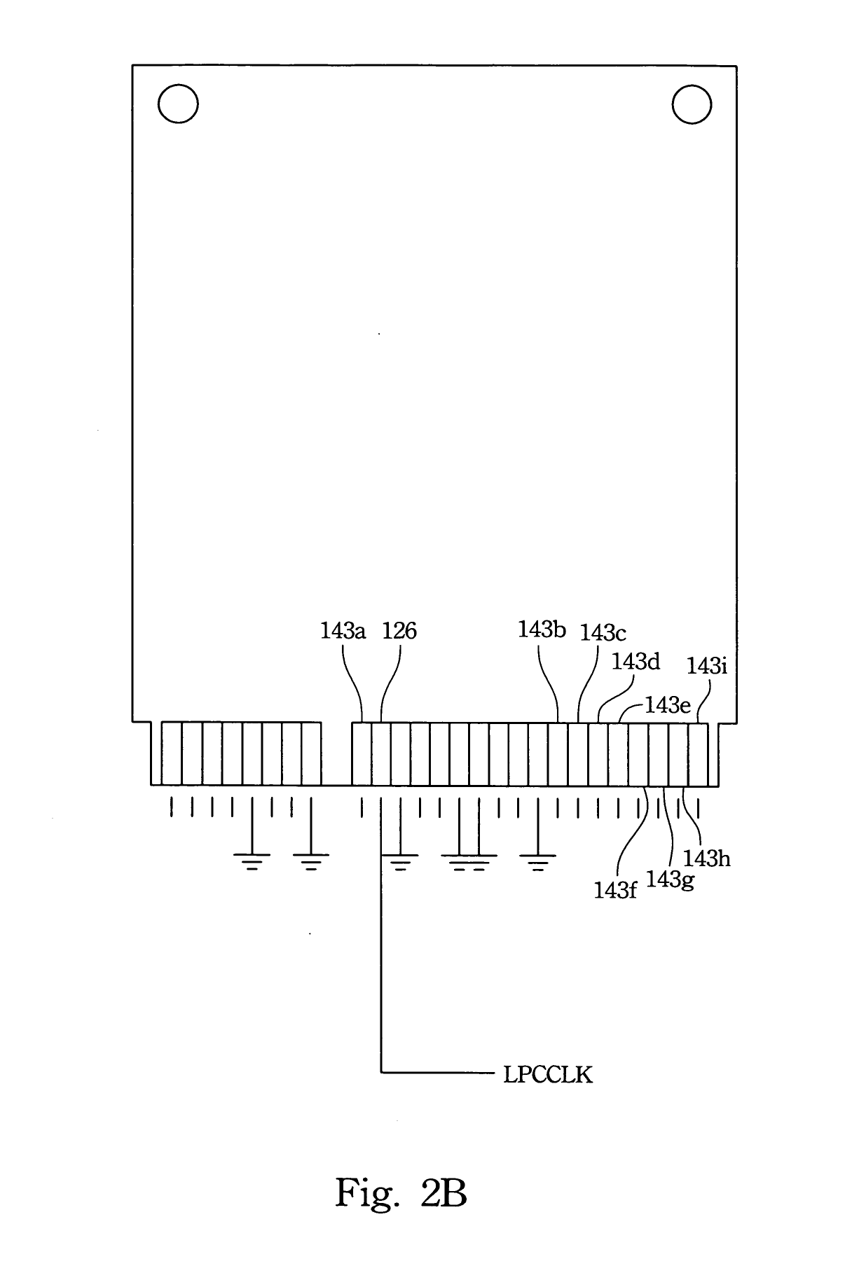

FIG. 1 illustrates a schematic diagram of a PCI-E debug card in accordance with a preferred embodiment of the present invention, and FIGS. 2A and 2B are respectively pin assignments on the bottom side and the top side of a PCI-E debug card in accordance with a preferred embodiment of the present invention. The PCI-E debug card 110 includes an insertion part 114 such as a connector, a low-pin-count pin set, a power pin 128, a ground pin 130, a decoder 116 and a display unit 140. The low-pin-count pin set includes a reset pin 124, a clock pin 126 and a plurality of data pins 122a˜122e, wherein each of the pins is for correspondingly electrically connecting to reserved pins (not shown in the figure) of a PCI-E slot 104.

The power pin 128 and the ground pin 130 are for respectively electrically connecting to a slot power pin and a slot ground pin (not shown in the figure) of the PCI-E slot 104. The decoder 116 is for decoding test data, transmitted through the data pins from a debug port such as port 80h 122a˜122e, to be a post code and then showing the post code by the display unit 140, such as an LED indicator.

The low-pin-count pin set refers to the pins which transfer signals complying with the LPC interface definition. The data pins herein include pins for signal LAD [3:0], which communicates address, control and data information over the LPC bus between a host and a peripheral, and a pin for signal LFRAME# which indicates the start of a new cycle, termination of a cycle, or a broken cycle.

In the embodiment, the present invention is applied in a laptop computer. The laptop computer requires efficient space utilization, and hence a smaller slot dimension, for example, a Mini PCI interface is employed for a laptop computer that corresponds to the PCI interface in a desktop version. Although a Mini PCI-E interface slot is used in the embodiment, it should not be assumed to limit the present invention. Various interfaces in the PCI-E family which provide various transfer rates such as PCI-E×16 are also included within the scope of the invention.

The debug card 110 includes a circuit board 112, a decoder 116 and an LED indicator. The circuit board 112 complies with the dimension of the Mini PCI-E specification, also called PCI-Express Mini Card, including an insertion part 114 for being inserted into the PCI-E slot 104 of the computer. As shown in FIGS. 2A and 2B, both the bottom side and the top side of the insertion part 114 have a plurality of pins: five data pins 122a˜122e and a reset pin 124 on the bottom side along with the clock pin 126 on the top side, constituting the low-pin-count pin set. The pins above are responsible for transmission of signals LAD [3:0], LFRAME#, LRESET# and LCLK, which are all defined in the LPC interface specification. Each pin of the low-pin-count pin set is designed to correspond to reserved pins of the PCI-E slot 104.

The data pins 122a˜122e serve as paths by which POST code data are transmitted from a debug port such as port 80h. The reset pin 124 is for a reset purpose and the clock pin 126 is for a clock signal transmission. The ground pin 130 and the power pin 128 correspond to a slot ground pin and a slot power pin of the PCI-E slot 104, that is, they are responsible for grounding and supplying power respectively; and when the debug card 110 is connected to the slot 104, the pins contact with the corresponding slot pins to achieve those purposes. Further, the top side of the debug card 110 includes a plurality of debug card reserved pins 143a˜1431.

When the debug card 110 is to be used, the insertion part 114 is aligned with and inserted into the PCI-E slot 104 on the circuit board 102. The insertion part 114 can be inserted without difficulty due to a dimensional match such that pins of the debug card 110 contact those of the PCI-E slot 104. During the POST procedure, generated test data are delivered to the debug port by BIOS where the data is in 8-bit form and represents a test result.

The test data are then transmitted through the low-pin-count pin set to the decoder 116 of the debug card 110 to be decoded. After the test data are decoded to be a POST code by the decoder 116, the LED indicator shows a specific number, the so-called POST code. Each number stands for a status report from the test which generally can be explained by descriptions written in a manual provided by the BIOS manufacturer. Therefore, test reports through the PCI-E interface are available with the present invention.

It should be noted that the display unit 140 is not limited to the LED indicator; a regular LED bulb can also be used. Also, different status reports may be presented by way of blinking a certain number of times or by arranging a plurality of LED bulbs.

The debug card 110 further includes a power indicating device 142, which is electrically connected to the power pin 128. The power indicating device 142 lights up when the debug card is supplied with proper power, notifying users of power supply status.

The present invention has at least the following advantage. The invention allows a computer to report POST results through a PCI-E interface, which is quickly becoming a mainstream interface, and hence facilitates maintenance of the computer system. Small and lightweight laptop computer applications are especially sure to get great advantage by both the PCI-E interface and the convenient way to check system status via the PCI-E interface provided by this invention.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A PCI-E debug card applicable to a PCI-E slot, comprising:
an insertion part for connecting to the PCI-E slot;
a low-pin-count pin set on the insertion part, comprising:
a reset pin for a reset signal transmission;
a clock pin for a clock signal transmission; and
a plurality of data pins, when the insertion part is connected with the PCI-E slot, the data pins, the reset pin and the clock pin contact with reserved pins of the PCI-E slot;
a power pin on the insertion part corresponding to a slot power pin of the PCI-E slot and electrically connected to a power source;
a ground pin on the insertion part corresponding to a slot ground pin of the PCI-E slot and electrically connected to a ground;
a decoder for decoding test data from the low-pin-count pin set to be a POST code; and
a display unit showing the POST code.

2. The PCI-E debug card of claim 1, further comprising a power indicating device electrically connected with the power pin for indicating a power supply status.

3. The PCI-E debug card of claim 1, wherein the display unit is an LED indicator.

4. The PCI-E debug card of claim 1, wherein the display unit is a regular LED bulb.

5. The PCI-E debug card of claim 1, wherein the data pins are in number of five.

6. The PCI-E debug card of claim 1, wherein the data pins and the reset pin are disposed on a bottom side of the insertion part and the clock pin is disposed on a top side of the insertion part.

7. A PCI-E debug card applicable to a Mini PCI-E slot, comprising:
a circuit board complying with a Mini PCI-E specification dimension for connecting to the Mini PCI-E slot;
a low-pin-count pin set, comprising:
a reset pin for a reset signal transmission;
a clock pin for a clock signal transmission; and
a plurality of data pins, when the insertion part is connected with the Mini PCI-E slot, the data pins, the reset pin and the clock pin contact with reserved pins of the Mini PCI-E slot;
a power pin on the insertion part corresponding to a slot power pin of the Mini PCI-E slot and electrically connected to a power source;
a ground pin on the insertion part corresponding to a slot ground pin of the Mini PCI-E slot and electrically connected to a ground;
a decoder for decoding test data from the low-pin-count pin set to be a POST code; and
a display unit showing the POST code.

8. The PCI-E debug card of claim 7, further comprising a power indicating device electrically connected with the power pin for indicating a power supply status.

9. The PCI-E debug card of claim 7, wherein the display unit is an LED indicator.

10. The PCI-E debug card of claim 7, wherein the display unit is a regular LED bulb.

11. The PCI-E debug card of claim 7, wherein the data pins are in number of five.

12. The PCI-E debug card of claim 7, wherein the data pins and the reset pin are disposed on a bottom side of the circuit board and the clock pin is disposed on a top side of the circuit board.
